(19) United States
(12) Patent Application Publication
(10) Pub. No.: US 2011/0027717 A1
(43) Pub. Date: Feb. 3, 2011

(54) PHOTORESIST COMPOSITION

(76) Inventors: Kiyoharu Tsutsumi, Hyogo (JP); Arimichi Okumura, Hyogo (JP)

Correspondence Address: BIRCH STEWART KOLASCH & BIRCH, PO BOX 747, FALLS CHURCH, VA, 22040-0747, US

(21) Appl. No.: 12/935,969

(22) PCT Filed: Apr. 2, 2009
(86) PCT No.: PCT/JP2009/001559

§ 371 Date: Oct. 1, 2010

(30) Foreign Application Priority Data
Apr. 4, 2008 (JP) 2008-098509

(51) Int. Cl. G03F 7/004; G03F 7/20

(52) U.S. Cl. 430/281.1; 430/325

(57) ABSTRACT

A photoresist composition contains a polyol compound and a vinyl ether compound, which polyol compound having an aliphatic group and an aromatic group bound alternately, and which aromatic group has an aromatic ring and two or more hydroxyl groups on the aromatic ring. The polyol compound can be prepared, for example, through an acid-catalyzed reaction, such as a Friedel-Crafts reaction, between an aliphatic polyol and an aromatic polyol. The aliphatic polyol is preferably an alicyclic polyol, whereas the aromatic polyol is preferably hydroquinone.

The photoresist composition gives a resist film showing excellent alkali solubility and high etching resistance and thereby gives a resist pattern with less LER and less pattern collapse.

### TECHNICAL FIELD

The present invention relates to a novel photoresist composition containing a polyol compound and a vinyl ether compound. The present invention also relates to a process for the formation of a resist film using the photoresist composition; to a resulting resist film obtained by the process; and to a process for the formation of a resist pattern using the resist film.

### BACKGROUND ART

Recent improvements in lithographic technologies rapidly move patterning for the production of semiconductor devices and liquid crystal displays to finer design rules. Such patterning in finer design rules has been generally achieved by adopting light sources having shorter wavelengths. Specifically, ultraviolet rays represented by g line (g ray) and i line (i ray) were customarily used, but commercial production of semiconductor devices using KrF excimer laser and ArF excimer laser has been launched. Further recently, lithography processes using extreme ultraviolet (EUV; having a wavelength of about 13.5 nm) and those using electron beams have been proposed as next-generation technologies succeeding to the lithography process using ArF excimer laser (193 nm).

Chemically-amplified resists are known as one of resist materials which have such high resolutions as to reproduce patterns with fine dimensions. The chemically-amplified resists each contain a base component capable of forming a film and capable of becoming soluble in an alkali by the action of an acid; and an acid generator component capable of generating an acid upon irradiation with light (upon exposure).

Such resist materials, when used for the formation of patterns, cause roughness of the top surface and sidewall surface of the patterns. The roughness was trivial in the past but has recently become a serious problem, because further higher resolutions are demanded in production typically of semiconductor devices in finer design rules. For example, when a line pattern is formed, the roughness of the sidewall surface of the pattern, i.e., line edge roughness (LER) causes a variation in line width. The variation in line width is desirably controlled to be about 10% or less of the ideal width, but LER more affects the variation in line width with decreasing pattern dimensions. However, customarily used polymers are difficult to give resist patterns with less LER, because they have a large average particle diameter of about several nanometers per one molecule.

An exemplary candidate for the reduction of LER by adopting a polymer having a small average particle diameter per one molecule is a resist composition described in Patent Document 1. This resist composition contains a polyhydric phenol compound, and an acid generator component capable of generating an acid upon exposure. The resist composition, however, is unsatisfactory in resolution and etching resistance, and the resulting resist pattern often suffers from pattern collapse. Specifically, under present circumstances, there has been found no resist composition which can give a resist pattern with less LER and with less pattern collapse, while showing excellent resolution and high etching resistance.

### CITATION LIST

### Patent Document

Patent Document 1: Japanese Unexamined Patent Application Publication (JP-A) No. 2006-78744

### SUMMARY OF INVENTION

### Technical Problem

Accordingly, an object of the present invention is to provide a novel photoresist composition which can give a resist pattern with less LER and less pattern collapse, while showing excellent resolution and high etching resistance.

Another object of the present invention is to provide a process for the formation of a resist film using the photoresist composition; a resist film formed by the process; and a process for the formation of a resist pattern using the resist film.

### Means for Solving the Problems

After intensive investigations to achieve the objects, the present inventors have found a photoresist composition containing a polyol compound and a vinyl ether compound, in which the polyol compound contains at least one aliphatic group and at least one aromatic group bound to each other alternately, and in which the aromatic group has at least one aromatic ring and two or more hydroxyl groups bound to the aromatic ring; and the present inventors have found that the polyol compound and the vinyl ether compound can be easily reacted with each other by heating the photoresist composition. The present inventors have also found that a polymer compound obtained through the reaction is satisfactorily insoluble or sparingly soluble in an alkaline developer and gives a resist pattern having excellent etching resistance while avoiding pattern collapse.

The present inventors have further found that the polymer compound obtained through the reaction between the polyol compound and the vinyl ether compound can be easily decomposed by the action of an acid, and this gives a resist pattern with less LER while exhibiting a high resolution. The present invention has been made based on these findings and further investigations.

Specifically, the present invention provides, in an embodiment, a photoresist composition which includes a polyol compound and a vinyl ether compound, in which the polyol compound contains at least one aliphatic group and at least one aromatic group bound to each other alternately, and the aromatic group has at least one aromatic ring and two or more hydroxyl groups bound to the aromatic ring.

The polyol compound is preferably a polyol compound obtained through an acid-catalyzed reaction between an aliphatic polyol and an aromatic polyol; and the acid-catalyzed reaction is preferably a Friedel-Crafts reaction.

The aliphatic polyol is preferably an alicyclic polyol, of which an adamantanepolyol having an adamantane ring and two or more hydroxyl groups bound at the tertiary positions of the adamantane ring is more preferred.

The aromatic polyol is preferably hydroquinone or a naphthalenepolyol.

The polyol compound preferably has a weight-average molecular weight of 500 to 5000.

The vinyl ether compound is preferably a multivalent vinyl ether compound.

In another embodiment, the present invention provides a process for the formation of a resist film. This process includes the steps of applying the photoresist composition to a base (substrate); and heating the applied composition to react the polyol compound and the vinyl ether compound with each other.

The present invention provides, in yet another embodiment, a resist film formed by the process for the formation of a resist film.

In addition, the present invention provides a process for the formation of a resist pattern. The process includes the steps of pattern-wise exposing the resist film; and developing the pattern-wise-exposed resist film.

### ADVANTAGES

The photoresist composition according to the present invention contains a polyol compound and a vinyl ether compound, which polyol compound has at least one aliphatic group and at least one aromatic group bound to each other alternately, and which aromatic group has at least one aromatic ring and two or more hydroxyl groups bound to the aromatic ring. When the photoresist composition is heated, the polyol compound and the vinyl ether compound can be easily reacted with each other to give a polymer compound for photoresists. The resulting polymer compound is insoluble or sparingly soluble in an alkali developer and gives a resist pattern with excellent etching resistance while avoiding pattern collapse. In addition, the polymer compound for photoresists can be easily decomposed by the action of an acid and can give a resist pattern with less LER while showing excellent resolution. For example, even in photolithography using extreme ultraviolet (EUV; having a wavelength of about 13.5 nm) so as to give a line-and-space pattern of about 22 nm, the polymer compound for photoresists can give a high-resolution resist pattern with a reduced LER of 2 nm or less.

### DESCRIPTION OF EMBODIMENTS

### Photoresist Compositions

Photoresist compositions according to the present invention each contain a polyol compound and a vinyl ether compound, which polyol compound contains at least one aliphatic group and at least one aromatic group bound to each other alternately, and which aromatic group has at least one aromatic ring and two or more hydroxyl groups bound to the aromatic ring.

The polyol compound has a structure where at least one aliphatic group and at least one aromatic group bound to each other alternately, the aromatic group having at least one aromatic ring and two or more hydroxyl groups bound to the aromatic ring. Examples of such polyol compounds include polyol compounds each having one unit (repeating unit) composed of one aliphatic group and one aromatic group bound to each other, such as a compound having one aliphatic group and one or more aromatic groups bound thereto, and a compound having one aromatic group and two or more aliphatic groups bound thereto; polyol compounds each having two or more of the repeating unit; and mixtures of these.

The polyol compound can be produced according to a variety of processes, such as a process of subjecting an aliphatic polyol and an aromatic polyol to an acid-catalyzed reaction; a process of subjecting an aliphatic multivalent halide and an aromatic polyol to an acid-catalyzed reaction; and a process of subjecting phenol and formaldehyde to an acid-catalyzed reaction or alkali-catalyzed reaction. Among them, the process of subjecting an aliphatic polyol and an aromatic polyol to an acid-catalyzed reaction is preferably adopted in the present invention to produce the polyol compounds synthetically.

The acid-catalyzed reaction between the aliphatic polyol and the aromatic polyol is preferably a Friedel-Crafts reaction.

(Aliphatic Polyols)

The aliphatic polyol is a compound having an aliphatic hydrocarbon group and two or more hydroxyl groups bound thereto and is represented by following Formula (1):

R—(OH)ₙ₁ (1)

wherein R represents an aliphatic hydrocarbon group; and n1 denotes an integer of 2 or more.

Examples of R in Formula (1) include chain aliphatic hydrocarbon groups, cyclic aliphatic (cycloaliphatic) hydrocarbon groups, and groups each having two or more of these groups bound to each other. Exemplary chain aliphatic hydrocarbon groups include alkyl groups having about 1 to 20 carbon atoms, such as methyl, ethyl, propyl, isopropyl, butyl, isobutyl, s-butyl, t-butyl, pentyl, hexyl, decyl, and dodecyl groups, of which those having about 1 to 10 carbon atoms are preferred, and those having about 1 to 3 carbon atoms are more preferred; alkenyl groups having about 2 to 20 carbon atoms, such as vinyl, allyl, and 1-butenyl groups, of which those having about 2 to 10 carbon atoms are preferred, and those having about 2 or 3 carbon atoms are more preferred; and alkynyl groups having about 2 to 20 carbon atoms, such as ethynyl and propynyl groups, of which those having about 2 to 10 carbon atoms are preferred, and those having about 2 or 3 carbon atoms are more preferred.

Exemplary cycloaliphatic hydrocarbon groups include cycloalkyl groups having about 3 to 20 members, such as cyclopropyl, cyclobutyl, cyclopentyl, cyclohexyl, and cyclooctyl groups, of which those having about 3 to 15 members are preferred, and those having about 5 to 8 members are more preferred; cycloalkenyl groups having about 3 to 20 members, such as cyclopentenyl and cyclohexenyl groups, of which those having about 3 to 15 members are preferred, and those having about 5 to 8 members are more preferred; and bridged hydrocarbon groups such as perhydronaphth-1-yl group, norbornyl, adamantyl, and tetracyclo[4.4.0.1^{2,5}.1^{7,10}]dodec-3-yl groups.

Exemplary hydrocarbon groups each having a chain aliphatic hydrocarbon group and a cycloaliphatic hydrocarbon group bound to each other include cycloalkyl-alkyl groups such as cyclopentylmethyl, cyclohexylmethyl, and 2-cyclohexylethyl groups, of which cycloalkyl-alkyl groups whose cycloalkyl moiety having 3 to 20 carbon atoms and whose alkyl moiety having 1 to 4 carbon atoms are preferred.

The hydrocarbon groups may each have one or more substituents, such as halogen atoms, oxo group, hydroxyl group, substituted oxy groups (e.g., alkoxy groups, aryloxy groups, aralkyloxy groups, and acyloxy groups), carboxyl group, substituted oxycarbonyl groups (e.g., alkoxycarbonyl groups, aryloxycarbonyl groups, and aralkyloxycarbonyl groups), substituted or unsubstituted carbamoyl groups, cyano group, nitro group, substituted or unsubstituted amino groups, sulfo group, and heterocyclic groups. The hydroxyl group and carboxyl group may be respectively protected by protecting groups customarily used in organic syntheses.

The aliphatic polyol for use herein is preferably an alicyclic polyol, for further higher etching resistance. The alicyclic polyol is a compound having an alicyclic skeleton, and the hydroxyl group may be bound to the alicyclic skeleton directly or indirectly through linkage groups. Exemplary linkage groups include alkylene groups (e.g., alkylene groups having 1 to 6 carbon atoms); and groups each including one or more of the alkylene groups and at least one group selected from the group consisting of —O—, —C(═O)—, —NH—, and —S— bound to each other.

Examples of the alicyclic polyol include alicyclic polyols such as cyclohexanediol, cyclohexanetriol, cyclohexanedimethanol, isopropylidenedicyclohexanol, decahydronaphthalenediol (decalindiol), and tricyclodecanedimethanol; and bridged alicyclic polyols of Formula (1) in which R is a ring selected from the group consisting of rings represented by following Formulae (2a) to (2j) or R is a ring containing two or more of these rings bound to each other, where two or more hydroxyl groups are bound to R.

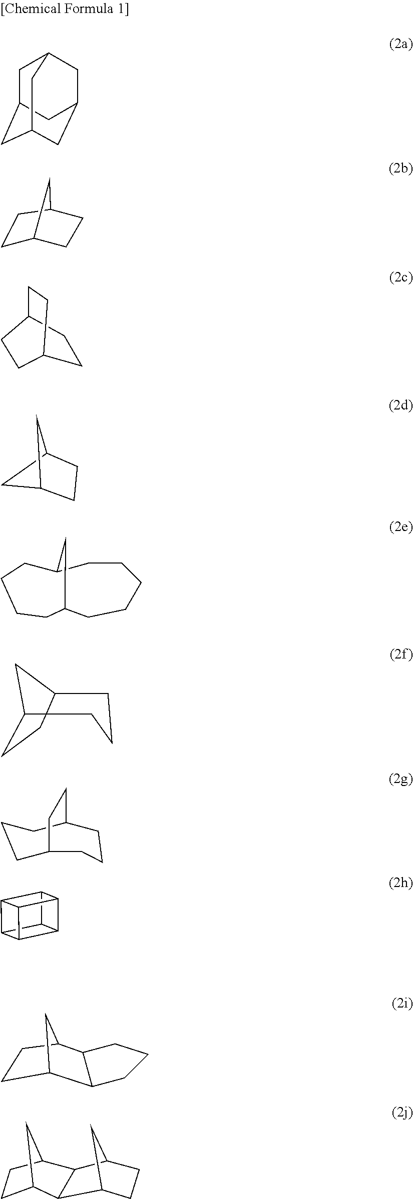

Of such aliphatic polyols, bridged alicyclic polyols are preferred, of which adamantanepolyols each having an adamantane ring (2a) and two or more hydroxyl groups bound at the tertiary positions of the adamantane ring are more preferred, for further higher etching resistance.

### (Aromatic Polyols)

The aromatic polyol for use in the present invention is a compound having at least one aromatic ring and two or more hydroxyl groups bound to the aromatic ring and is represented by following Formula (3):

R′—(OH)ₙ₂ (3)

wherein R′ represents an aromatic hydrocarbon group; and n2 denotes an integer of 2 or more. When R′ has two or more aromatic rings, the two or more hydroxyl groups may be bound to the same aromatic ring or to different aromatic rings.

Examples of R′ in Formula (3) include aromatic hydrocarbon groups and groups each having an aromatic hydrocarbon group to which a chain aliphatic hydrocarbon group and/or cycloaliphatic hydrocarbon group is bound. Exemplary aromatic hydrocarbon groups include aromatic hydrocarbon groups having about 6 to 14 carbon atoms, such as phenyl and naphthyl groups, of which those having about 6 to 10 carbon atoms are preferred. Examples of the chain aliphatic hydrocarbon group and of the cycloaliphatic hydrocarbon group are as with the exemplary chain aliphatic hydrocarbon groups and cycloaliphatic hydrocarbon groups as R.

Exemplary groups each having an aromatic hydrocarbon group to which a chain aliphatic hydrocarbon group is bound include alkyl-substituted aryl groups, such as phenyl group or naphthyl group on which about one to four alkyl groups having 1 to 4 carbon atoms are substituted.

The aromatic hydrocarbon group may have one or more substituents, such as halogen atoms, oxo group, hydroxyl group, substituted oxy groups (e.g., alkoxy groups, aryloxy groups, aralkyloxy groups, and acyloxy groups), carboxyl group, substituted oxycarbonyl groups (e.g., alkoxycarbonyl groups, aryloxycarbonyl groups, and aralkyloxycarbonyl groups), substituted or unsubstituted carbamoyl groups, cyano group, nitro group, substituted or unsubstituted amino groups, sulfo group, and heterocyclic groups. The hydroxyl group and carboxyl group may be respectively protected by protecting groups customarily used in organic syntheses. An aromatic or nonaromatic heterocyclic ring may be fused (condensed) to the ring of the aromatic hydrocarbon group.

Examples of the aromatic polyol include hydroquinone; resorcinol; naphthalenepolyols such as 1,3-dihydroxynaphthalene and 1,4-dihydroxynaphthalene; biphenols; bis(4-hydroxyphenyl)methane; bisphenol-A; and 1,1,1-(4-hydroxyphenyl)ethane. Among them, hydroquinone and naphthalenepolyols are easily available and are therefore advantageously used in the present invention.

Exemplary acid catalysts for use in the acid-catalyzed reaction include Lewis acids such as aluminum chloride, iron(III) chloride, tin(IV) chloride, and zinc(II) chloride; and protonic acids such as hydrogen fluoride (HF), sulfuric acid, p-toluenesulfonic acid, and phosphoric acid. Each of these can be used alone or in combination. Typically in the production of semiconductor devices, organic acids such as sulfuric acid and p-toluenesulfonic acid are preferably used as the acid catalysts, because the production should be performed while avoiding contamination of metal components. Such acid catalysts are used in an amount of, for example, about 0.01 to 10 moles and preferably about 0.1 to 5 moles, per 1 mole of the aliphatic polyol.

The acid-catalyzed reaction is performed in the presence of a solvent inert to the reaction, or in the absence of a solvent. Examples of the solvent include hydrocarbons such as hexane, cyclohexane, and toluene; halogenated hydrocarbons such as methylene chloride, 1,2-dichloroethane, chloroform, carbon tetrachloride, and chlorobenzene; chain or cyclic ethers such as diethyl ether, dimethoxyethane, tetrahydrofuran, and dioxane; nitriles such as acetonitrile and benzonitrile; esters such as ethyl acetate and n-butyl acetate; carboxylic acids such as acetic acid; amides such as N,N-dimethylformamide; ketones such as acetone and methyl ethyl ketone; nitro compounds such as nitromethane and nitrobenzene; and mixtures of them.

The reaction temperature in the acid-catalyzed reaction can be chosen as appropriate according typically to the types of reaction components. Typically, when 1,3,5-adamantanetriol and hydroquinone are used as the aliphatic polyol and the aromatic polyol, respectively, the reaction is performed at a temperature of typically around room temperature (25° C.) to 200° C. and preferably around 50° C. to 150° C. The reaction can be performed according to any system such as batch system, semi-batch system, or continuous system.

The aromatic polyol is used in an amount of generally about 1.0 to 100 moles, preferably about 3.0 to 50 moles, and more preferably about 5.0 to 20 moles, per 1 mole of the aliphatic polyol. The aromatic polyol may be used in large excess.

The reaction gives a corresponding polyol compound. After the completion of the reaction, the reaction product can be separated and purified by a common separation/purification procedure such as adjustment of acidity or alkalinity, filtration, concentration, crystallization, washing, recrystallization, and/or column chromatography. A solvent for use in crystallization (crystallization solvent) can be any solvent in which the produced polyol compound is insoluble, and examples thereof include hydrocarbons such as hexane, heptane, and cyclohexane. In a preferred embodiment of the present invention, a solvent mixture is used as the crystallization solvent, which solvent mixture contains both a solvent in which the produced polyol compound is insoluble and another solvent in which the material aliphatic polyol and aromatic polyol are soluble. This is because the use of the solvent mixture helps to remove the residual material aliphatic polyol and aromatic polyol more easily, resulting in higher purification efficiency. Examples of the solvent in which the material aliphatic polyol and aromatic polyol are soluble include ethers such as tetrahydrofuran; ketones such as acetone and 2-butanone; esters such as ethyl acetate; and alcohols such as methanol and ethanol. The mixing ratio of respective solvents in the solvent mixture can be adjusted as appropriate. As used herein the term “crystallization” (deposition) also means and includes precipitation or settlement.

The reaction product often contains components insoluble in an alkaline developer. Examples of such components include (i) components having relatively high molecular weights of more than 2000; and (ii) compounds, even having molecular weights of 1000 to 2000, containing phenolic hydroxyl groups of the polyol compound which have been sealed or blocked typically through transesterification with the solvent during the reaction. If a polyol compound containing components insoluble in an alkaline developer is used for resist, the insoluble components may adversely affect the roughness in patterning and/or may cause particles during development, and the particles may remain as foreign substances in the formed resist pattern. To avoid these, it is preferred to provide the step of mixing a solution of the polyol compound in a solvent with a poor solvent with respect to a compound having one or more phenolic hydroxyl groups to deposit or separate as a different layer (to separate as a liquid) hydrophobic impurities to thereby remove the hydrophobic impurities. This step, when provided, helps to remove the components efficiently and to produce a high-purity polyol compound efficiently, and the resulting polyol compound is useful for the preparation of a resist composition which gives a resist pattern with less LER while exhibiting excellent resolution and high etching resistance.

Exemplary solvents for the formation of a solution of the polyol compound include ethers such as tetrahydrofuran; ketones such as acetone and 2-butanone; esters such as ethyl acetate and n-butyl acetate; and alcohols such as methanol and ethanol. Each of these solvents can be used alone or in combination. The solution of the polyol compound to be subjected to the removal operation of hydrophobic impurities can be either a reaction solution (reaction mixture) obtained as a result of the acid-catalyzed reaction, or a solution obtained by subjecting the reaction solution to an operation such as dilution, concentration, filtration, adjustment of acidity or alkalinity, and/or solvent exchange.

The solution of the polyol compound to be subjected to the removal operation of hydrophobic impurities has a content of the polyol compound of typically 1 to 40 percent by weight and preferably 3 to 30 percent by weight.

Examples of the poor solvent with respect to a compound having one or more phenolic hydroxyl groups include solvents having a solubility (25° C.) of phenol of 1 g/100 g or less. Specific examples of the poor solvent with respect to a compound having one or more phenolic hydroxyl groups include hydrocarbons including aliphatic hydrocarbons such as hexane and heptane, and alicyclic hydrocarbons such as cyclohexane; solvent mixtures each containing water and one or more water-miscible organic solvents (e.g., alcohols such as methanol and ethanol; ketones such as acetone; nitriles such as acetonitrile; and cyclic ethers such as tetrahydrofuran); and water. Each of these solvents can be used alone or in combination. The poor solvent is used in an amount of typically 1 to 55 parts by weight and preferably 5 to 50 parts by weight, per 100 parts by weight of the solution containing the polyol compound.

Upon mixing of the solution of the polyol compound and the poor solvent, it is acceptable to add the poor solvent to the solution of the polyol compound or to add the solution of the polyol compound to the poor solvent; but it is more preferred to add the poor solvent gradually to the solution of the polyol compound.

The deposited or layer-separated hydrophobic impurities can be removed according to a procedure such as filtration, centrifugal separation, or decantation. The solution after the removal of the hydrophobic impurities is further mixed with another portion of the poor solvent with respect to a compound having one or more phenolic hydroxyl groups to thereby allow the polyol compound to deposit or to be separated as a different layer. In this procedure, it is acceptable to add the poor solvent to the solution after the removal of the hydrophobic impurities or to add the solution after the removal of the hydrophobic impurities to the poor solvent; but it is more preferred to add the solution after the removal of the hydrophobic impurities to the poor solvent. The amount of the poor solvent in this step is typically 60 to 1000 parts by weight and preferably 65 to 800 parts by weight, per 100 parts by weight of the solution after the removal of the hydrophobic impurities (solution containing the polyol compound).

The deposited or layer-separated polyol compound can be recovered typically through filtration, centrifugal separation, and/or decantation. The poor solvent for use in the deposition or layer-separation of hydrophobic impurities may be the same as or different from the poor solvent for use in the deposition or layer-separation of the target polyol compound. Where necessary, the obtained polyol compound is subjected to drying.

The polyol compound for use in the present invention has a weight-average molecular weight (Mw) of about 500 to 5000, preferably about 1000 to 3000, and more preferably about 1000 to 2000. A polyol compound, if having a weight-average molecular weight of more than 5000, may have an excessively large particle diameter and may tend to insufficiently help to reduce LER. In contrast, a polyol compound, if having a weight-average molecular weight of less than 500, may tend to cause insufficient thermal stability. The polyol compound has a molecular weight distribution (Mw/Mn) of typically about 1.0 to 2.5. The symbol Mn indicates a number-average molecular weight, and both Mn and Mw are values in terms of a standard polystyrene.

Examples of the polyol compound for use in the present invention include polyol compounds represented by following Formulae (4a), (4b), and (4c), in which “s”, “t”, and “u” may be the same as or different from one another and each represent an integer of 0 or more; and the symbol “ . . . ” indicates that a repeating unit of “adamantane ring-hydroquinone” may be further repeated or terminated here.

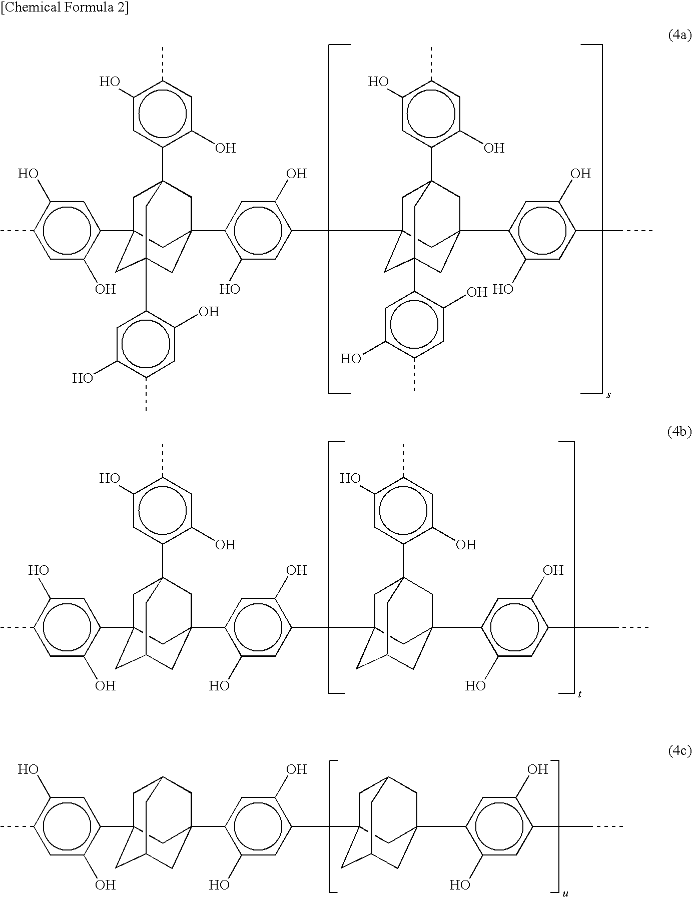

(Vinyl Ether Compounds)

The vinyl ether compound is used to form protecting groups for preventing the dissolution of the polymer compound in an alkaline developer. Examples thereof include monovinyl ether compounds; and multivalent vinyl ether compounds such as divinyl ether compounds, trivinyl ether compounds, tetravinyl ether compounds, and hexavinyl ether compounds. Each of these vinyl ether compounds can be used alone or in combination. In a preferred embodiment of the present invention, one or more divinyl ether compounds, or a mixture of one or more divinyl ether compounds and one or more monovinyl ether compounds is used, because the resulting polymer compound for photoresists obtained from the polyol compound and the vinyl ether compound through heating remains as liquid, thereby maintains its capability of forming a resist film, and shows excellent workability even when the polyol compound has a small weight-average molecular weight, and the polymer compound for photoresists gives a resist film having improved etching resistance, and the formed resist pattern shows less pattern collapse.

When the resulting photoresist composition is adopted to EUV exposure, the vinyl ether compound preferably has a molecular weight equal to or higher than a predetermined value, because contamination of apparatuses due to outgassing should be avoided in such EUV exposure, and such a vinyl ether compound having a molecular weight equal to or higher than a predetermined value less causes outgassing. Specifically, the vinyl ether compound in this use preferably has a molecular weight of about 100 to 500. A vinyl ether compound, if having an excessively small molecular weight, may tend to increase the risk of contamination of the optical system due to outgassing occurring as a result of EUV exposure. In contrast, a vinyl ether compound, if having an excessively large molecular weight, may have an excessively high viscosity, and its application to a base may tend to be difficult; and the vinyl ether compound may remain as a residue on the base or substrate after development to cause post-develop defects. Such vinyl ether compounds can be synthetically prepared, for example, by reacting vinyl acetate with an alcohol in the presence of an iridium catalyst.

Exemplary vinyl ether compounds for use in the present invention include compounds represented by following Formulae (5a) to (5m) and (6a) to (6n):

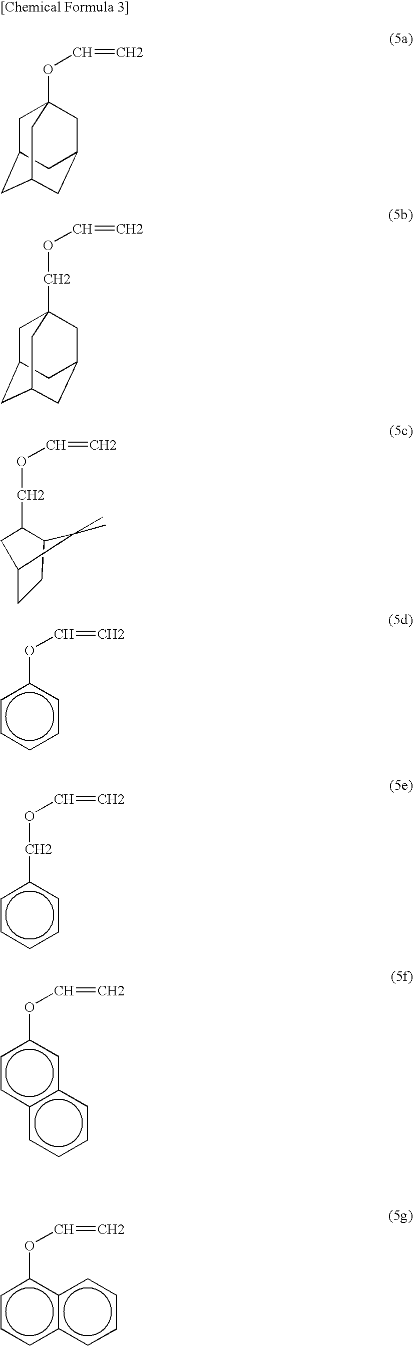

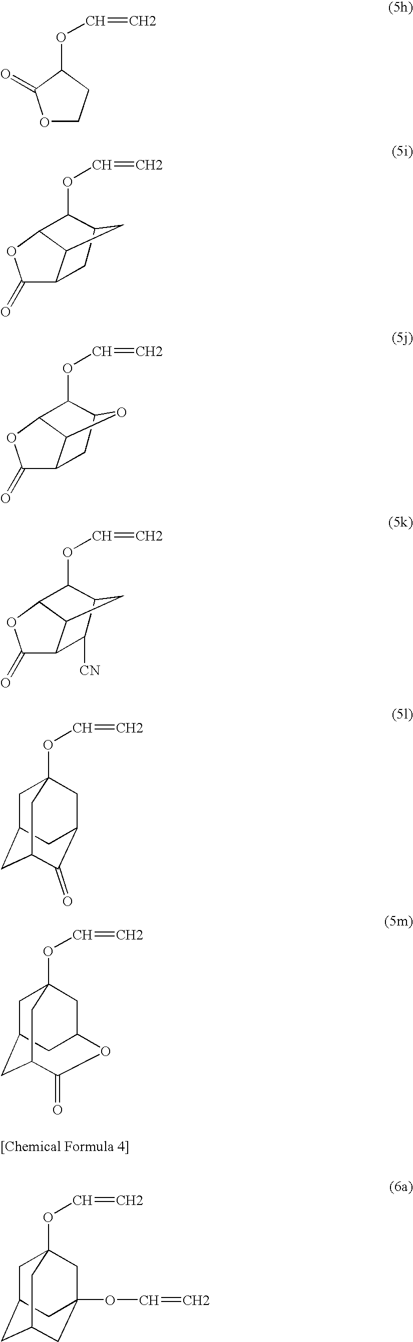

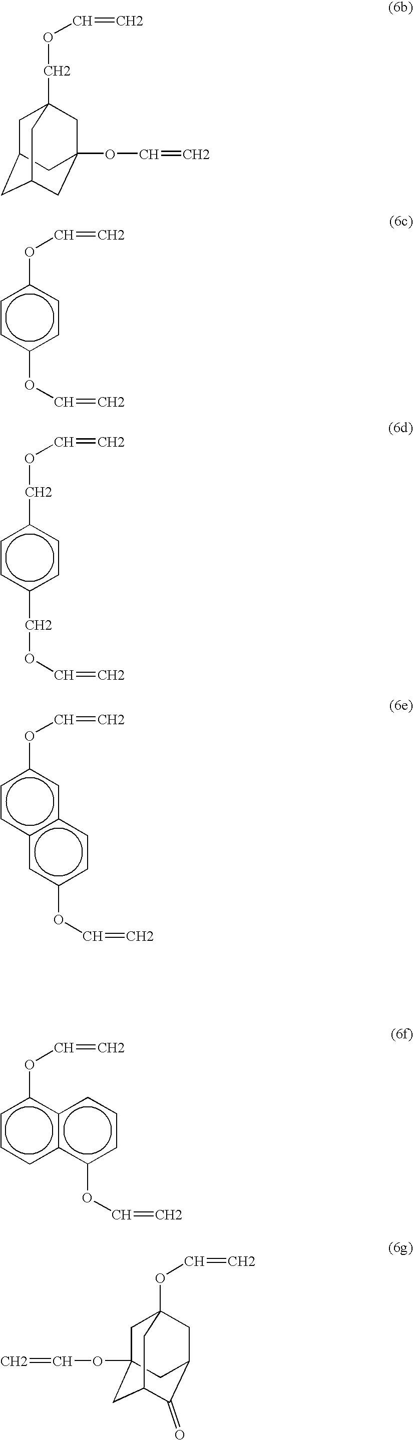

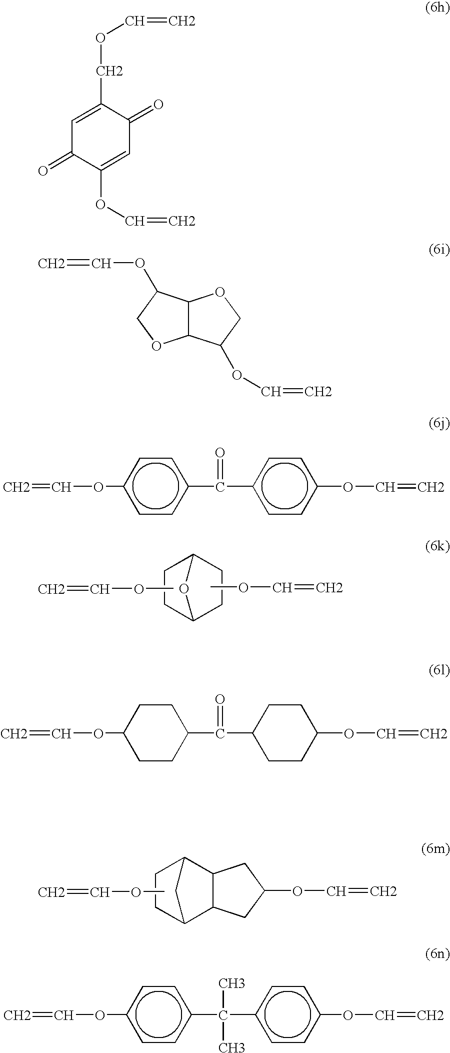

The photoresist compositions according to the present invention each contain the polyol compound and the vinyl ether compound. The contents of the polyol compound and the vinyl ether compound can be adjusted as appropriate according to the numbers of phenolic hydroxyl groups and vinyl ether groups so that the photoresist composition contains vinyl ether groups in a number of typically about 30 to 100, and preferably about 50 to 80, per 100 phenolic hydroxyl groups. If the photoresist composition contains vinyl ether groups in a number of less than 30, the photoresist composition may not give a polymer compound which is sufficiently insoluble or sparingly soluble in an alkaline developer, because the phenolic hydroxyl groups may not be protected sufficiently in the polymer compound. Thus, upon patterning of the resist film, unexposed portions of the resist film may be dissolved in or swell with an alkali developer, and it may be difficult to reproduce a target pattern accurately. In contrast, the photoresist composition, if containing vinyl ether groups in a number of more than 100, may give a polyol compound containing residual unreacted molecules of the vinyl ether compound, and this may cause outgassing upon exposure. In addition, the resulting resist film may have a lower glass transition temperature (Tg) and may be difficult to reproduce the target pattern accurately upon patterning.

The photoresist compositions according to the present invention preferably further contain other components such as a light-activatable acid generator (photo-acid-generating agent) and a resist solvent.

Exemplary light-activatable acid generators usable in the present invention include common or known compounds that efficiently generate an acid upon exposure, including diazonium salts, iodonium salts (e.g., diphenyliodo hexafluorophosphate), sulfonium salts (e.g., triphenylsulfonium hexafluoroantimonate, triphenylsulfonium hexafluorophosphate, triphenylsulfonium methanesulfonate, and triphenylsulfonium trifluoromethanesulfonate), sulfonic acid esters [e.g., 1-phenyl-1-(4-methylphenyl)sulfonyloxy-1-benzoylmethane, 1,2,3-trisulfonyloxymethylbenzene, 1,3-dinitro-2-(4-phenylsulfonyloxymethyl)benzene, and 1-phenyl-1-(4-methylphenylsulfonyloxymethyl)-1-hydroxy-1-benzoylmethane], oxathiazole derivatives, s-triazine derivatives, disulfone derivatives (e.g., diphenyldisulfone), imide compounds, oxime sulfonates, diazonaphthoquinone, and benzoin tosylate. Each of these light-activatable acid generators can be used alone or in combination.

The amount of the light-activatable acid generators can be chosen as appropriate according typically to the strength of the acid generated upon irradiation with light and the proportion of the polyol compound, within ranges of typically about 0.1 to 30 parts by weight, preferably about 1 to 25 parts by weight, and more preferably about 2 to 20 parts by weight, per 100 parts by weight of the polyol compound.

Examples of the resist solvent include glycol solvents, ester solvents, ketone solvents, and mixtures of these solvents. Among them, preferred are propylene glycol monomethyl ether, propylene glycol monomethyl ether acetate, ethyl lactate, methyl isobutyl ketone, methyl amyl ketone, and mixtures of them; of which more preferred are solvents each containing at least propylene glycol monomethyl ether acetate. Examples thereof include a single solvent of propylene glycol monomethyl ether acetate alone; a solvent mixture containing both propylene glycol monomethyl ether acetate and propylene glycol monomethyl ether; and a solvent mixture containing both propylene glycol monomethyl ether acetate and ethyl lactate.

The photoresist compositions have concentrations of the polyol compound of typically about 2 to 20 percent by weight and preferably about 5 to 15 percent by weight, although the concentrations can be set as appropriate according typically to the thickness of the coated film (resist film) within such a range that the composition can be applied (coated) to a base (substrate). A photoresist composition having an excessively high concentration of the polyol compound may tend to be difficult to apply to a base because of its excessively high viscosity. In contrast, a photoresist composition having an excessively low concentration of the polyol compound may tend to be difficult to form a resist film. The photoresist compositions according to the present invention may further contain other components including alkali-soluble components such as alkali-soluble resins (e.g., novolak resins, phenol resins, imide resins, and carboxyl-group containing resins); and colorants (e.g., dyestuffs).

[Process for Formation of Resist Film]

A process for the formation of a resist film according to the present invention includes the steps of applying the photoresist composition to a base to give a film thereon; and heating the applied film to react the polyol compound and the vinyl ether compound with each other.

The polyol compound for use in the present invention has phenolic hydroxyl groups which impart solubility in an alkaline developer, and the phenolic hydroxyl groups are protected by protecting groups capable of easily leaving (eliminating) by the action of an acid, so that the polyol compound is sparingly soluble or insoluble in an alkaline developer.

In the process according to the present invention, the mixture (composition) of the polyol compound and the vinyl ether compound is heated to react phenolic hydroxyl groups of the polyol compound and vinyl ether group(s) of the vinyl ether compound with each other to form acetal structures, which acetal structures will easily leave by the action of an acid.

In a preferred embodiment, a multivalent vinyl ether compound is used as the vinyl ether compound. In this embodiment, the process can give a resist film which is further resistant to pattern collapse and exhibits further higher etching resistance, because two or more molecules of the polyol compound can be bound to each other through the protecting group.

Exemplary materials for the base (substrate) include silicon wafers, metals, plastics, glass, and ceramics. The application of the photoresist composition can be performed using a customary coating device such as spin coater, dip coater, or roller coater. The resist film has a thickness of typically about 0.01 to 10 μm and preferably about 0.03 to 1 μm.

The heating can be performed using a heating device such as hot plate or oven. The heating may be performed under conditions of a temperature of around 150° C. to 250° C. (preferably around 150° C. to 200° C.) for a duration of about one minute to one hour (preferably about 1 to 5 minutes).

Resist films according to the present invention, formed by the formation process, can give resist patterns which have excellent etching resistance while avoiding LER and pattern collapse, because the resist films include a polymer compound for photoresists, which is obtained through the reaction between the polyol compound and the vinyl ether compound and is easily decomposable with an acid. The resist films are therefore advantageously usable, as resist films having such high resolution as to reproduce patterns with fine dimensions, in a variety of uses such as the production of semiconductor devices and liquid crystal displays.

[Process for Formation of Resist Pattern]

A process for the formation of a resist pattern according to the present invention includes the steps of pattern-wise exposing the resist film and developing the pattern-wise-exposed resist film. Specifically, a resist pattern is formed by exposing the resist film to light through a predetermined mask to form a latent image pattern, and developing the exposed resist film.

For the exposure, any of light rays of different wavelengths, such as ultraviolet rays and X-rays, can be used. Typically, g line, i line, excimer laser (e.g., XeCl, KrF, KrCl, ArF, or ArCl laser), and EUV (extreme ultraviolet) are generally used for semiconductor resist use. The exposure is performed at an exposure energy of typically about 1 to 1000 mJ/cm² and preferably about 10 to 500 mJ/cm².

The exposure causes the light-activatable acid generator to generate an acid. Next, a post-exposure baking (hereinafter also referred to as “PEB treatment”) is performed to allow the generated acid to act on protecting groups of the polymer compound for photoresists to leave rapidly from the polymer compound, to thereby give phenolic hydroxyl groups that help the polymer compound to be soluble in an alkaline developer. The development with the alkaline developer therefore gives a predetermined pattern with a high accuracy. The PEB treatment may be performed typically under conditions at a temperature of about 50° C. to 180° C. for a duration of about 0.1 to 10 minutes and preferably about 1 to 3 minutes.

The post-exposure-baked resist film is subjected to development with a developer to remove exposed portions therefrom. Thus, the resist film is patterned. The development is performed according to a procedure such as dispensing development (puddle development), dipping development, and vibration/dipping development. An alkaline aqueous solution (e.g., a 0.1 to 10 percent by weight aqueous tetramethylammonium hydroxide solution) can be used as the developer.

The base (substrate) after development is preferably washed with running water and air-dried with compressed air or compressed nitrogen. Thus, a resist pattern is formed on the substrate.

The process for the formation of a resist pattern according to the present invention uses a resist film formed from the photoresist composition according to the present invention and can thereby give a resist pattern having such a high resolution as to give a line-and-space pattern of 0.05 μm or less (e.g., 0.01 to 0.05 μm), while avoiding LER and pattern collapse.

### EXAMPLES

The present invention will be illustrated in further detail with reference to several working examples below. It should be noted, however, that these examples are never construed to limit the scope of the present invention.

GPC (gel permeation chromatography) measurements were performed under following conditions:

Column: Three TSKgel SuperHZM-M columns

Column temperature: 40° C.

Eluent: Tetrahydrofuran

Flow rate of eluent: 0.6 mL/min.

Sample concentration: 20 mg/mL

Injection volume: 10 μL

### Preparation Example 1

In a 200-mL three-necked flask equipped with a Dimroth condenser, a thermometer, and a stirring bar were placed 2.18 g of 1,3,5-adamantanetriol, 7.82 g of hydroquinone, 13.51 g of p-toluenesulfonic acid, and 56.67 g of n-butyl acetate, followed by stirring thoroughly. Next, the flask was purged with nitrogen and submerged in an oil bath heated to 140° C., to start heating with stirring. After being kept heating under reflux for 2 hours, the flask was cooled.

The cooled reaction solution was transferred from the flask to a separatory funnel, washed with 80 g of distilled water, and further washed with five portions of 65 g of distilled water. The washed reaction solution had a weight of 55.4 g. The washed reaction solution was poured into 500 g of n-heptane, to deposit orange fine particles. The fine particles were collected through filtration, dried at 60° C. for 12 hours, and thereby yielded 5.8 g of a polyol compound 1. The prepared polyol compound 1 was subjected to a GPC measurement and found to have a weight-average molecular weight in terms of standard polystyrene of 1100 and a molecular weight distribution of 1.69.

### Preparation Example 2

In a 200-mL three-necked flask equipped with a Dimroth condenser, a thermometer, and a stirring bar were placed 0.739 g of 1,3,5-adamantanetriol, 3.98 g of hydroquinone, 18.01 g of p-toluenesulfonic acid, and 18.01 g of n-butyl acetate, followed by stirring thoroughly. Next, the flask was purged with nitrogen and submerged in an oil bath heated to 140° C., to start heating with stirring. After being kept heating under reflux for 2 hours, the flask was cooled.

The cooled reaction solution was transferred from the flask to a separatory funnel and washed with six portions of 20 g of distilled water. The washed reaction solution had a weight of 15.6 g. The washed reaction solution was poured into 100 g of n-heptane, to deposit orange fine particles. The fine particles were collected through filtration, dried at 60° C. for 12 hours, and thereby yielded 2.2 g of a polyol compound 2. The prepared polyol compound 2 was subjected to a GPC measurement and found to have a weight-average molecular weight in terms of standard polystyrene of 800 and a molecular weight distribution of 1.26.

### Preparation Example 3

In a 200-mL three-necked flask equipped with a Dimroth condenser, a thermometer, and a stirring bar were placed 2.18 g of 1,3,5-adamantanetriol, 7.82 g of hydroquinone, 13.51 g of p-toluenesulfonic acid, and 56.67 g of n-butyl acetate, followed by stirring thoroughly. Next, the flask was purged with nitrogen and submerged in an oil bath heated to 100° C. to start heating with stirring. After being kept heating under reflux for 2 hours, the flask was cooled.

The cooled reaction solution was transferred from the flask to a separatory funnel, washed with 80 g of distilled water, and further washed with five portions of 65 g of distilled water. The washed reaction solution had a weight of 55.4 g. The washed reaction solution was poured into 500 g of n-heptane, to deposit orange fine particles. The fine particles were collected through filtration, dried at 60° C. for 12 hours, and thereby yielded 5.2 g of a polyol compound 3. The prepared polyol compound 3 was subjected to a GPC measurement and found to have a weight-average molecular weight in terms of standard polystyrene of 1310 and a molecular weight distribution of 2.08.

### Preparation Example 4

In a 200-mL three-necked flask equipped with a Dimroth condenser, a thermometer, and a stirring bar were placed 5.85 g of 1,3,5-adamantanetriol, 24.18 g of hydroquinone, 15.04 g of p-toluenesulfonic acid, and 170.02 g of n-butyl acetate, followed by stirring thoroughly. Next, the flask was purged with nitrogen and submerged in an oil bath heated to 140° C., to start heating with stirring. After being kept heating under reflux for one hour, the flask was cooled.

The cooled reaction solution was transferred from the flask to a separatory funnel, washed with 100 g of distilled water, and further washed with five portions of 100 g of distilled water. The washed reaction solution had a weight of 181.4 g. Into the washed reaction solution was poured 116.6 g of n-heptane to cause an orange liquid to be separated as a different layer and to settle. The settlement was removed using a separatory funnel, the resulting upper layer was further added to 207.9 g of heptane to settle a slightly yellow liquid. The liquid was separated, dried at 45° C. for 8 hours, and thereby yielded 16.5 g of a polyol compound 4. The prepared polyol compound 4 was subjected to a GPC measurement and found to have a weight-average molecular weight in terms of standard polystyrene of 1000 and a molecular weight distribution of 1.13.

### Example 1

A photoresist composition 1 having a polyol compound concentration of 15 percent by weight was prepared by mixing 100 parts by weight of the polyol compound 1 prepared in Preparation Example 1, 50 parts by weight of 1,4-di(vinyloxymethyl)cyclohexane, 5 parts by weight of triphenylsulfonium trifluoromethanesulfonate, and an appropriate amount of propylene glycol monomethyl ether acetate.

The prepared photoresist composition 1 was applied to a silicon wafer through spin coating and heated on a hot plate at a temperature of 150° C. for 180 seconds to form a resist film 1 having a thickness of 500 nm. The resist film 1 was exposed to KrF excimer laser beams through a mask at an irradiance level of 30 mJ/cm² and then subjected to a PEB treatment at a temperature of 100° C. for 60 seconds. Next, the resist film was developed with a 2.38% aqueous tetramethylammonium hydroxide solution for 60 seconds, rinsed with pure water, and thereby yielded a 0.20-μm line-and-space pattern.

### Examples 2 and 3

The procedure of Example 1 was performed, except that the polyol compound 2 prepared in Preparation Example 2 and the polyol compound 3 prepared in Preparation Example 3 were used in Example 2 and Example 3, respectively, instead of the polyol compound 1 prepared in Preparation Example 1, to yield 0.20-μm line-and-space patterns in both examples.

### Example 4

A photoresist composition 4 having a polyol compound concentration of 15 percent by weight was prepared by mixing 100 parts by weight of the polyol compound 1 prepared in Preparation Example 1, 50 parts by weight of 1,3-divinyloxyadamantane, 5 parts by weight of triphenylsulfonium trifluoromethanesulfonate, and an appropriate amount of propylene glycol monomethyl ether acetate.

The prepared photoresist composition 4 was applied to a silicon wafer through spin coating and heated on a hot plate at a temperature of 150° C. for 180 seconds to form a resist film 4 having a thickness of 500 nm. The resist film 4 was exposed to KrF excimer laser beams through a mask at an irradiance level of 30 mJ/cm² and then subjected to a PEB treatment at a temperature of 100° C. for 60 seconds. Next, the resist film was developed with a 2.38% aqueous tetramethylammonium hydroxide solution for 60 seconds, rinsed with pure water, and thereby yielded a 0.20-μm line-and-space pattern.

### Examples 5 and 6

The procedure of Example 4 was performed, except that the polyol compound 2 prepared in Preparation Example 2 and the polyol compound 3 prepared in Preparation Example 3 were used in Example 5 and Example 6, respectively, instead of the polyol compound 1 prepared in Preparation Example 1, to yield 0.20-μm line-and-space patterns in both examples.

### Example 7

A photoresist composition 7 having a polyol compound concentration of 15 percent by weight was prepared by mixing 100 parts by weight of the polyol compound 1 prepared in Preparation Example 1, 50 parts by weight of 2,6-dioxa-4,8-divinyloxybicyclo[3.3.0]octane, 5 parts by weight of triphenylsulfonium trifluoromethanesulfonate, and an appropriate amount of propylene glycol monomethyl ether acetate.

The prepared photoresist composition 7 was applied to a silicon wafer through spin coating and heated on a hot plate at a temperature of 150° C. for 180 seconds to form a resist film 7 having a thickness of 500 nm. The resist film 7 was exposed to KrF excimer laser beams through a mask at an irradiance level of 30 mJ/cm² and then subjected to a PEB treatment at a temperature of 100° C. for 60 seconds. Next, the resist film was developed with a 2.38% aqueous tetramethylammonium hydroxide solution for 60 seconds, rinsed with pure water, and thereby yielded a 0.20-μm line-and-space pattern.

### Examples 8 and 9

The procedure of Example 7 was performed, except that the polyol compound 2 prepared in Preparation Example 2 and the polyol compound 3 prepared in Preparation Example 3 were respectively used in Example 8 and Example 9 instead of the polyol compound 1 prepared in Preparation Example 1, to yield 0.20-μm line-and-space patterns in both examples.

### Example 10

The procedure of Example 1 was performed, except that the polyol compound 4 prepared in Preparation Example 4 was used in Example 10 instead of the polyol compound 1 prepared in Preparation Example 1, to yield a 0.20-μm line-and-space pattern.

### INDUSTRIAL APPLICABILITY

The photoresist compositions according to the present invention can undergo reactions easily by heating, to give polymer compounds for photoresists, and the polymer compounds are insoluble or sparingly soluble in an alkaline developer and give resist patterns having excellent etching resistance while avoiding pattern collapse. In addition, the polymer compounds for photoresists are easily decomposable by the action of an acid and thereby give resist films with excellent resolution while avoiding LER.

1. A photoresist composition, comprising a polyol compound and a vinyl ether compound, the polyol compound containing at least one aliphatic group and at least one aromatic group bound to each other alternately, the aromatic group having at least one aromatic ring and two or more hydroxyl groups bound to the aromatic ring.

2. The photoresist composition according to claim 1, wherein the polyol compound is a product of an acid-catalyzed reaction between an aliphatic polyol and an aromatic polyol.

3. The photoresist composition according to claim 2, wherein the acid-catalyzed reaction is a Friedel-Crafts reaction.

4. The photoresist composition according to claim 2 or 3, wherein the aliphatic polyol is an alicyclic polyol.

5. The photoresist composition according to claim 2, wherein the aliphatic polyol is an adamantanepolyol having an adamantane ring and two or more hydroxyl groups bound at the tertiary positions of the adamantane ring.

6. The photoresist composition according to claim 2, wherein the aromatic polyol is hydroquinone.

7. The photoresist composition according to claim 2, wherein the aromatic polyol is a naphthalenepolyol.

8. The photoresist composition according to claim 1, wherein the polyol compound has a weight-average molecular weight of 500 to 5000.

9. The photoresist composition according to claim 1, wherein the vinyl ether compound is a multivalent vinyl ether compound.

10. A process for the formation of a resist film, the process comprising the steps of applying the photoresist composition according to claim 1 to a base; and heating the applied composition to react the polyol compound and the vinyl ether compound with each other.

11. A resist film formed by the process for the formation of a resist film, according to claim 10.

12. A process for the formation of a resist pattern, the process comprising the steps of pattern-wise exposing the resist film according to claim 11; and developing the pattern-wise-exposed resist film.
